(19) United States
(12) Patent Application Publication
(10) Pub. No.: US 2009/0128210 A1
(43) Pub. Date: May 21, 2009

(54) SEMICONDUCTOR INTEGRATED CIRCUIT AND ELECTRONIC CIRCUIT

(75) Inventor: Takuji YAMAMOTO, Kawasaki (JP)

Correspondence Address: ARENT FOX LLP, 1050 CONNECTICUT AVENUE, N.W., SUITE 400, WASHINGTON, DC, 20036, US

(73) Assignee: FUJITSU LIMITED, Kawasaki (JP)

(21) Appl. No.: 12/269,323

(22) Filed: Nov. 12, 2008

(30) Foreign Application Priority Data
Nov. 20, 2007 (JP) 2007-300834

(51) Int. Cl. H03K 3/289

(52) U.S. Cl. 327/202

(57) ABSTRACT

An electric circuit has a first differential circuit for transmitting input data to a first node, a second differential circuit for holding the first node data, a first clock transmission circuit for flowing a first current in accordance with a clock signal, and a first transformer circuit for transformer-coupling the first differential circuit with the first clock transmission circuit, and the second differential circuit with the first clock transmission circuit.

### CROSS-REFERENCE TO RELATED APPLICATIONS

This application is based upon and claims the benefit of priority from the prior Japanese Patent Application No. 2007-300834, filed on Nov. 20, 2007, the entire content of which is incorporated herein by reference.

### BACKGROUND

The present invention generally relates to a semiconductor integrated circuit, and particularly to a flip-flop circuit.

CMOS process miniaturization and resultant higher device operation speeds allow significantly high-speed communication using CMOS semiconductor integrated circuits. Wired communication, such as an optical transmission system operating at a frequency, for example, higher than 10 Gbps, and wireless communication and radars using, for example, a millimeter wave band ranging from 60 to 100 GHz are feasible by using CMOS devices. In such applications, a flip-flop circuit operating at very high-speed and low power supply voltage is necessary as a D-type flip flop circuit (D-F/F) used as a data decision circuit and a divider circuit used in a PLL. The

FIG. 1 shows an exemplary configuration of a conventional flip-flop circuit having a master-slave configuration. The flip-flop circuit 10 includes NMOS transistors 11 to 24 and resister elements R1 to R4. The flip-flop circuit shown in FIG. 1 is a circuit that latches a differential signal. In general, in a semiconductor integrated circuit operating at high speed, a circuit having a differential configuration is used in consideration of superiority in relative accuracy, superiority in common mode noise with respect to variation in temperature and power supply, and other properties.

A master-side latch includes NMOS transistors 11 to 17. A slave-side latch includes NMOS transistors 18 to 24. In the master-side latch and the slave-side latch, the NMOS transistors 17 and 24 operate as current sources for supplying a current, which may be a fixed current, to differential circuits.

In the master-side latch, when a clock signal CLK is at a high level, the NMOS transistor 15 is conducting and the differential circuit that includes the NMOS transistors 11 and 12 operates. For example, when a differential signal including a data signal DATA at a high level and a data signal /DATA at a low level is provided, the NMOS transistor 11 becomes conducting and the NMOS transistor 12 becomes non-conducting. Nodes A and B therefore become low and high levels, respectively. At this point, an inverted clock signal /CLK is at the low level, and hence the NMOS transistor 16 is non-conducting. The differential circuit including the NMOS transistors 13 and 14 therefore does not operate.

When the inverted clock signal /CLK then changes to the high level, the NMOS transistor 16 becomes conducting, and the differential circuit including the NMOS transistors 13 and 14 operates. In the example described above, since the node A is at the low level and the node B is at the high level, the NMOS transistor 13 is conducting and the NMOS transistor 14 is non-conducting, and the data state in which the node A is at the low level and the node B is at the high level is maintained. On the other hand, since the clock signal CLK changes to the low level, the NMOS transistor 15 becomes non-conducting and the differential circuit including the NMOS transistors 11 and 12 stops operating. As a result of the above operation, the data are held in the master-side latch.

At this point, since the inverted clock signal /CLK is at the high level in the slave-side latch, the NMOS transistor 22 is conducting and the differential circuit including the NMOS transistors 18 and 19 operates. Since the node A is at the low level and the node B is at the high level, the NMOS transistor 18 is non-conducting and the NMOS transistor 19 is conducting, and a node C becomes the high level and a node D becomes the low level. At this point, the clock signal CLK is at the low level, and the NMOS transistor 23 is non-conducting. The differential circuit including the NMOS transistors 20 and 21 therefore does not operate.

When the clock signal CLK then changes to the high level, the NMOS transistor 23 becomes conducting, and the differential circuit including the NMOS transistors 20 and 21 operates. In the example described above, since the node C is at the high level and the node D is at the low level, the NMOS transistor 20 is non-conducting and the NMOS transistor 21 is conducting, and the data state in which the node C is at the high level and the node D is at the low level is maintained. Also, the inverted clock signal /CLK changes to the low level, the NMOS transistor 22 becomes non-conducting and the differential circuit including the NMOS transistors 18 and 19 stops operating. As a result of the above operation, the data are held in the slave-side latch, and the data are outputted as output data OUT.

As described above, two latches, each of which transmit input data to an output terminal when a clock input is at a first signal level (high level/low level) and hold output data when the clock input is at a second signal level (low level/high level), are coupled in series. Connecting two such latches in series allows input data to be acquired at the rising edge or the falling edge of the clock signal and allows output data to be held during one cycle of the clock signal.

In the configuration shown in FIG. 1, three transistor-based channels are coupled in series between a power supply voltage VDD and a ground voltage VSS. Considering the resistor elements R1 to R4, the number of vertical stacks is four. To operate the flip-flop circuit shown in FIG. 1 at high speed in a stable manner, all three vertically stacked transistors preferably operate in saturated regions.

In a CMOS device, withstand voltage limitation of a transistor requires that a low power supply voltage is used. It is therefore difficult to operate each of the three stacked transistors in saturated regions in the configuration shown in FIG. 1. Such a situation may degrade high-speed operation characteristics and cause malfunctions.

### SUMMARY

According to an aspect of the invention, an electric circuit has a first differential circuit for transmitting input data to a first node, a second differential circuit for holding first node data, a first clock transmission circuit for flowing a first current in accordance with a clock signal, and a first transformer circuit for transformer-coupling the first differential circuit with the first clock transmission circuit, and the second differential circuit with the first clock transmission circuit.

### BRIEF DESCRIPTION OF THE DRAWINGS

FIG. 1 shows an example of a master-slave flip-flop circuit of related art;

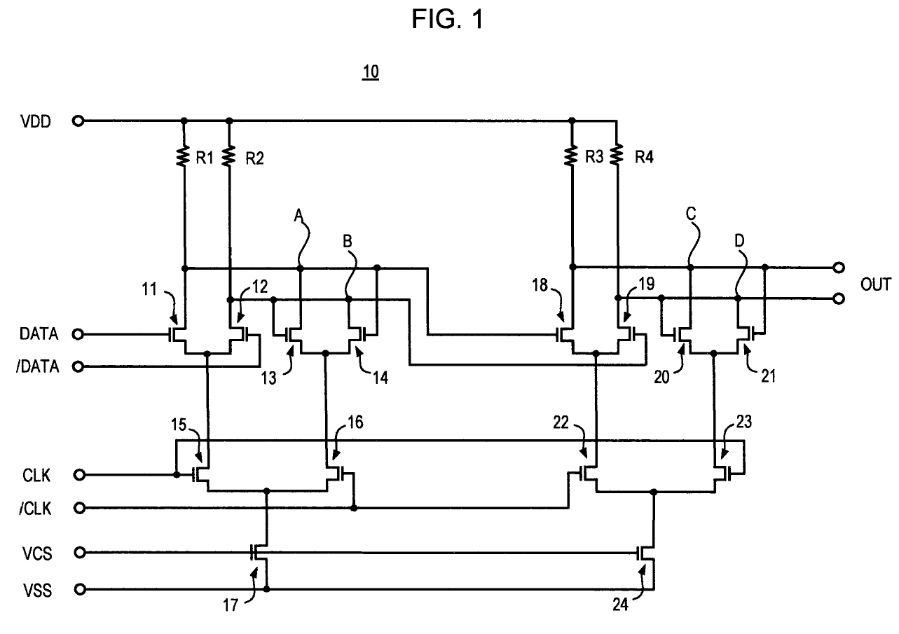

FIG. 2 shows a master-slave flip-flop circuit according to an embodiment of the present invention;

FIG. 3 diagrammatically shows the waveforms of currents I1 to I6;

FIG. 4 shows a flip-flop circuit according to another embodiment of the present invention;

FIG. 5 shows a flip-flop circuit according to still another embodiment of the present invention;

FIG. 6 shows a PLL circuit using a flip-flop circuit according to an embodiment of the present invention;

FIG. 7 shows an optical communication system using a flip-flop circuit according to an embodiment of the present invention;

FIG. 8 shows an example of a transmitter that is used in a wireless communication system and to which an embodiment of the present invention is applied;

FIG. 9 shows an example of a receiver that is used in a wireless communication system and to which an embodiment of the present invention is applied;

FIG. 10 shows a structure of a transformer circuit applicable to an embodiment of the present invention;

FIG. 11 shows the layout of inductor elements shown in FIG. 10;

FIG. 12 shows another structure of a transformer circuit applicable to an embodiment of the present invention; and

FIG. 13 shows the layout of inductor elements shown in FIG. 12.

### PREFERRED EMBODIMENT

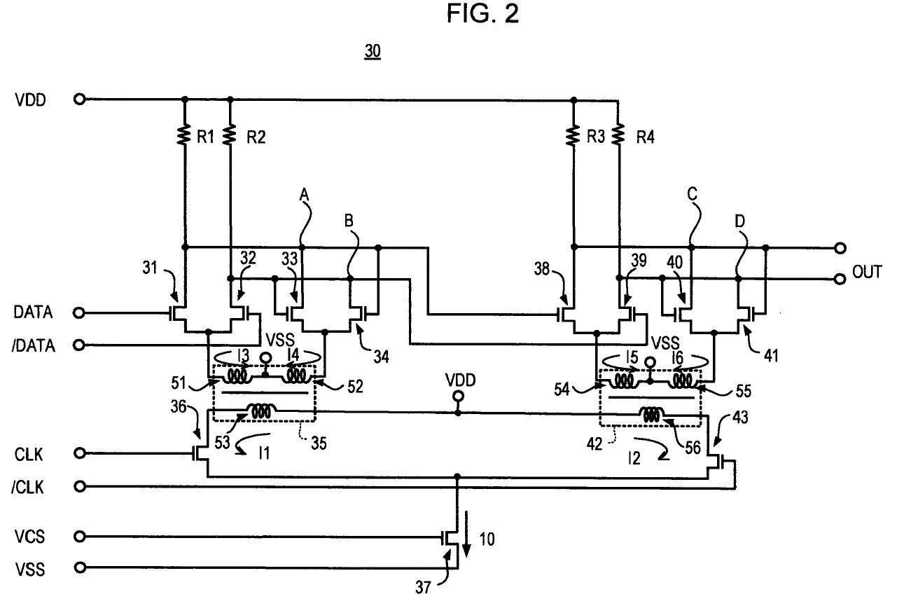

FIG. 2 shows a master-slave flip-flop circuit according to an embodiment of the present invention. The flip-flop circuit 30 includes NMOS transistors 31 to 34, a transformer circuit 35, NMOS transistors 37 to 41, a transformer circuit 42, an NMOS transistor 43, and resistor elements R1 to R4.

A master-side latch includes the NMOS transistors 31 to 34. A slave-side latch includes the NMOS transistors 38 to 41. The master-side latch includes a first differential circuit having the NMOS transistors 31 and 32 and a second differential circuit having the NMOS transistors 33 and 34. The first differential circuit responds to a first signal level of a clock signal CLK, for example, a high level, to operate and transmit input data DATA and /DATA to predetermined nodes A and B. The second differential circuit responds to a second signal level of the clock signal CLK, for example, a low level, to operate and hold data at the predetermined nodes A and B. The master-side latch further includes a clock transmission circuit having an NMOS transistor 36. The clock transmission circuit conducts a current according to the clock signal CLK. The master-side latch further includes the transformer circuit 35 that couples the first differential circuit and the second differential amplifier circuit with the clock transmission circuit.

The transformer circuit 35 includes a first inductor element 51 coupled to the first differential circuit, a second inductor element 52 coupled to the second differential circuit, and a third inductor element 53 transformer-coupled with the first and second inductor elements 51 and 52, and also coupled to the clock transmission circuit.

In the slave-side latch, the transformer circuit 42 includes a first inductor element 54 coupled to a first differential circuit including the NMOS transistors 38 and 39, a second inductor element 55 coupled to a second differential circuit including the NMOS transistors 40 and 41, and a third inductor element 56 transformer-coupled with the first and second inductor elements 54 and 55, and also coupled to a clock transmission circuit that includes the NMOS transistor 43.

The NMOS transistor 37 operates as a current source for supplying a current, which may be a fixed current, to the NMOS transistors 36 in the master-side latch and the NMOS transistor 43 in the slave-side latch.

In the master-side latch, when the clock signal CLK changes from the low level to the high level, the NMOS transistor 36 becomes conducting and a current I1 increases. The change in magnetic flux produced in the third inductor element 53 due to the change in the current I1 results in an electromotive force that causes a current to flow through the first inductor element 51 in the arrowed direction labeled as current I3 in FIG. 2. The magnitude of the current induced by the electromotive force is proportional to the current I1 so that the magnetic flux shared by the first inductor element 51 and the third inductor element 53 is kept at a fixed magnitude. The current induced by the electromotive force is added to the stationary current flowing from VDD to VSS, whereby the total current I3 increases and the differential circuit including the NMOS transistors 31 and 32 operates. For example, when a differential signal including a data signal DATA at the high level and a data signal /DATA at the low level is provided, the NMOS transistor 31 becomes conducting and the NMOS transistor 32 becomes non-conducting, and the node A becomes the low level and the node B becomes the high level.

At this point, in the second inductor element 52, the change in magnetic flux produced in the third inductor element 53 due to the change in the current I1 described above results in an electromotive force that causes a current to flow in the direction opposite the arrowed direction labeled as current I4. The magnitude of the current induced by the electromotive force is proportional to the current I1 so that the magnetic flux shared by the second inductor element 52 and the third inductor element 53 is kept at a fixed magnitude. The current produced by the total power cancels the stationary current flowing from VDD to VSS, and the total current I4 decreases.

When the clock signal CLK changes from the high level to the low level, the NMOS transistor 36 becomes non-conducting and the current I1 decreases. The change in magnetic flux produced in the third inductor element 53 due to the change in the current I1 results in an electromotive force that causes a current to flow through the second inductor element 52 in the arrowed direction labeled as current I4. The magnitude of the current induced by the electromotive force is proportional to the current I1 so that the magnetic flux shared by the second inductor element 52 and the third inductor element 53 is kept at a fixed magnitude. The current induced by the electromotive force is added to the stationary current flowing from VDD to VSS, whereby the total current I4 increases and the differential circuit including the NMOS transistors 33 and 34 operates. In the example described above, since the node A is at the low level and the node B is at the high level, the NMOS transistor 33 is conducting and the NMOS transistor 34 is non-conducting, and the data state in which the node A is at the low level and the node B is at the high level is maintained.

At this point, in the first inductor element 51, the change in magnetic flux produced in the third inductor element 53 due to the change in the current I1 described above results in an electromotive force that causes a current to flow in the direction opposite the arrowed direction labeled as current I3. The magnitude of the current induced by the electromotive force is proportional to the current I1 so that the magnetic flux shared by the first inductor element 51 and the third inductor element 53 is kept at a fixed magnitude. The current induced by the electromotive force cancels the stationary current flowing from VDD to VSS, whereby the total current I3 decreases, and the differential circuit including the NMOS transistors 31 and 32 stops operating. As a result of the above operation, the data DATA and /DATA are held in the master-side latch.

At this point, since an inverted clock signal /CLK changes from the low level to the high level on the slave-side latch, the NMOS transistor 43 becomes conducting and a current I2 increases. The change in magnetic flux produced in the third inductor element 56 due to the change in the current I2 results in an electromotive force that causes a current to flow through the first inductor element 54 in the arrowed direction labeled as current I5. The magnitude of the current induced by the electromotive force is proportional to the current I2 so that the magnetic flux shared by the first inductor element 54 and the third inductor element 56 is kept at a fixed magnitude. The current induced by the electromotive force is added to the stationary current flowing from VDD to VSS, whereby the total current I5 increases and the differential circuit including the NMOS transistors 38 and 39 operates. Since the node A is at the low level and the node B is at the high level, the NMOS transistor 38 is non-conducting and the NMOS transistor 39 is conducting, and the node C becomes the high level and the node D becomes the low level.

At this point, in the second inductor element 55, the change in magnetic flux produced in the third inductor element 56 due to the change in the current I2 described above results in an electromotive force that causes a current to flow in the direction opposite the arrowed direction labeled as current I6. The magnitude of the current induced by the electromotive force is proportional to the current I2 so that the magnetic flux shared by the second inductor element 55 and the third inductor element 56 is kept at a fixed magnitude. The current induced by the electromotive force cancels the stationary current flowing from VDD to VSS, and the total current I6 decreases.

When the inverted clock signal /CLK then changes from the high level to the low level, the NMOS transistor 43 becomes non-conducting and the current I2 decreases. The change in magnetic flux produced in the third inductor element 56 due to the change in the current I2 results in an electromotive force that causes a current to flow through the second inductor element 55 in the arrowed direction labeled as current I6. The magnitude of the current induced by the electromotive force is proportional to the current I2 so that the magnetic flux shared by the second inductor element 55 and the third inductor element 56 is kept at a fixed magnitude. The current induced by the electromotive force is added to the stationary current flowing from VDD to VSS, whereby the total current I6 increases and the differential circuit including the NMOS transistors 40 and 41 operates. In the example described above, since the node C is at the high level and the node D is at the low level, the NMOS transistor 40 is non-conducting and the NMOS transistor 41 is conducting, and the data state in which the node C is at the high level and the node D is at the low level is maintained.

At this point, in the first inductor element 54, the change in magnetic flux produced in the third inductor element 56 due to the change in the current I2 described above results in an electromotive force that causes a current to flow in the direction opposite the arrowed direction labeled as I5. The magnitude of the current induced by the electromotive force is proportional to the current I2 so that the magnetic flux shared by the first inductor element 54 and the third inductor element 56 is kept at a fixed magnitude. The current induced by the electromotive force cancels the stationary current flowing from VDD to VSS, whereby the total current I5 decreases to a sufficiently small value, and the differential circuit including the NMOS transistors 38 and 39 stops operating. As a result of the above operation, the data are held in the slave-side latch and outputted as output data OUT.

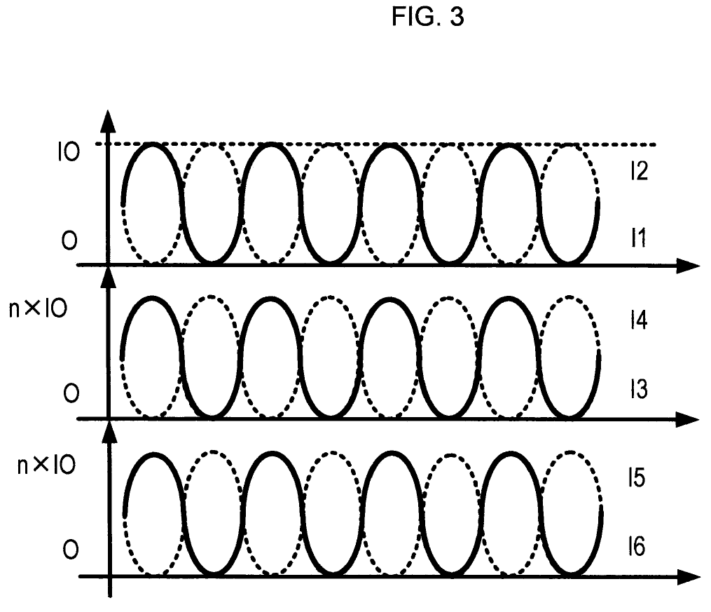

FIG. 3 shows the change in the currents I1 to I6 described above. As shown in FIG. 3, the current I3 having a magnitude of n×I0, which is proportional to the magnitude I0 of the current I1, flows as a current that is in phase with the current I1. The current I4 having a magnitude of n×I0, which is proportional to the magnitude I0 of the current I1, flows as a current that is in opposite phase with the current I1. Further, the current I5 having a magnitude of n×I0, which is proportional to the magnitude I0 of the current I2, flows as a current that is in opposite phase with the current I2. The current I6 having a magnitude of n×I0, which is proportional to the magnitude I0 of the current I2, flows as a current that is in phase with the current I2.

As described above, two latches, each of which transmit input data to an output terminal in response to a first signal level of a clock input and hold output data in response to a second signal level of the clock input, are coupled in series. Connecting two such latches in series allows the input data to be transmitted to an output node in response to the transition of the clock signal from the first signal level to the second signal level, and allows the data at the output node to be held during one cycle of the clock signal. The clock transmission circuits that include the NMOS transistors 36 and 43 through which a current according to the clock signal flows are coupled with the flip-flop circuit via the transformer circuits 35 and 42. In the configuration shown in FIG. 2, it is not necessary to provide a voltage between both terminals of the element, for example, inductor element 51, 52, 54, or 55, that controls ON/OFF of the currents.

Therefore, in the configuration shown in FIG. 2, to operate the flip-flop circuit in the data signal-side circuit of which only one transistor-based channel is coupled shown in FIG. 2 at high speed in a stable manner, a drain-source voltage high enough to operate the one-tier transistor in the saturated region may be applied between the power supply voltage VDD and the ground voltage VSS.

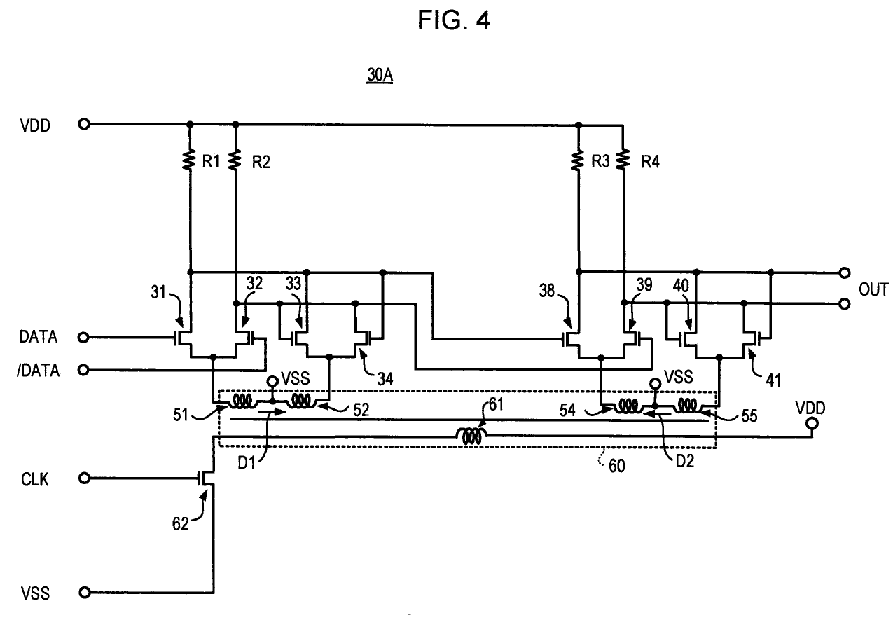

FIG. 4 shows a flip-flop circuit according to another embodiment of the present invention. In FIG. 4, the same components as those in FIG. 2 have the same reference numerals and description thereof will be omitted.

The flip-flop circuit 30A shown in FIG. 4 includes one transformer circuit 60 instead of the two transformer circuits 35 and 42 in the flip-flop circuit 30 shown in FIG. 2. The transformer circuit 60 includes a first inductor element 51 coupled to a first differential circuit having NMOS transistors 31 and 32, a second inductor element 52 coupled to a second differential circuit having NMOS transistors 33 and 34, a third inductor element 54 coupled to a third differential circuit having NMOS transistors 38 and 39, a fourth inductor element 55 coupled to a fourth differential circuit having NMOS transistors 40 and 41, a fifth inductor element 61 transformer-coupled with the first and fourth inductor elements and coupled to a clock transmission circuit having an NMOS transistor 62.

The transformer circuit 60 produces, in response to a first signal level, for example, a high level, of a clock signal CLK,an electromotive force that causes a current to flow through the first and second inductor elements 51 and 52 in the direction indicated by the arrow D1, and produces an electromotive force that causes a current to flow through the first and second inductor elements 54 and 55 in the direction indicated by the arrow D2. The transformer circuit 60 also produces, in response to a second signal level, for example, a low level, of the clock signal CLK, an electromotive force that causes a current to flow through the first and second inductor elements 51 and 52 in the direction opposite the direction indicated by the arrow D1, and an electromotive force that causes a current to flow through the first and second inductor elements 54 and 55 in the direction opposite the direction indicated by the arrow D2. Using the thus configured transformer circuit 60 allows the master-side latch and the slave-side latch in the flip-flop circuit 30A to operate in the same manner as the master-side latch and the slave-side latch in the flip-flop circuit 30.

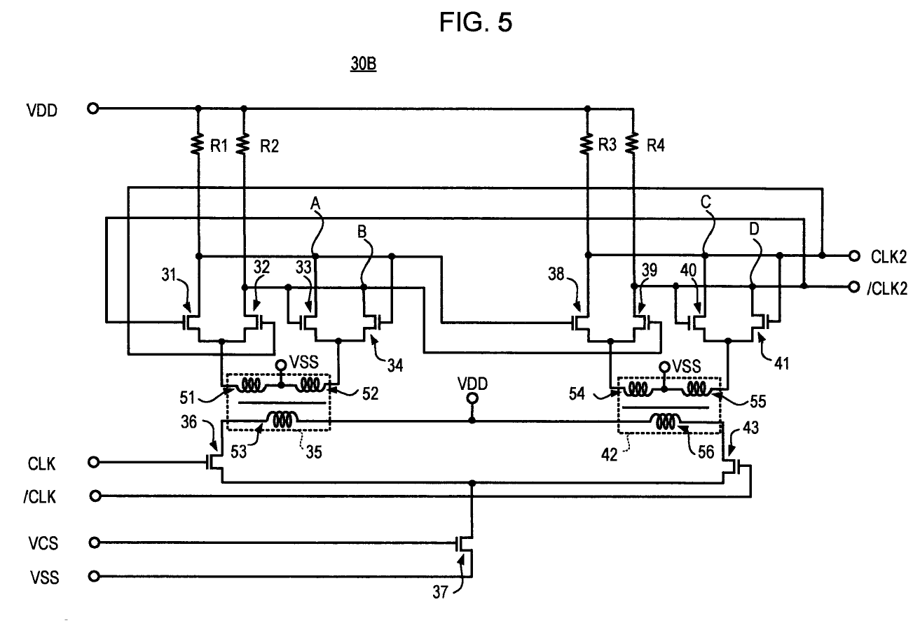

FIG. 5 shows a flip-flop circuit according to another embodiment of the present invention. In FIG. 5, the same components as those in FIG. 2 have the same reference numerals and description thereof will be omitted.

In the flip-flop circuit 30B shown in FIG. 5, an output node is coupled with an input node to supply data from the output node as input data. Based on clock signals CLK and /CLK, clock signals CLK2 and /CLK2, whose frequency is one-half the frequency of the clock signals CLK and /CLK, can be produced. That is, the flip-flop circuit 30B shown in FIG. 5 can serve as a divider circuit that halves a frequency. Such a divider circuit can be used, for example, in a PLL circuit. It is noted that a one-half divider circuit may be formed by coupling the output with the input in the flip-flop circuit 30A shown in FIG. 4.

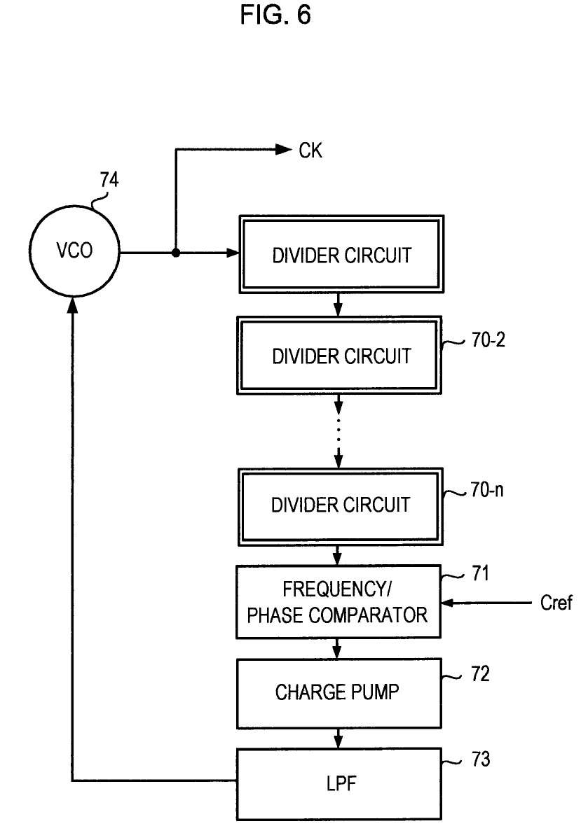

FIG. 6 shows a PLL circuit having divider circuits that use flip-flop circuits according to an embodiment of the present invention. The PLL circuit shown in FIG. 6 includes one or more divider circuits 70-1 to 70-n, a frequency/phase comparator 71, a charge pump 72, a lowpass filter (LPF) 73, and a voltage controlled oscillator (VCO) 74.

Each of the divider circuits 70-1 to 70-n is a divider circuit that halves a frequency, and the divider circuits 70-1 to 70-n as a whole divides a frequency by 2ⁿ. At least one of the divider circuits 70-1 to 70-n is a divider circuit having the same configuration as that shown in FIG. 5. Using the flip-flop circuit shown in FIG. 2 or 4, which uses transformation coupling to transmit a clock, as a divider circuit allows a high-speed clock signal to be stably divided even when a low power supply voltage is used.

The frequency/phase comparator 71 compares the frequency or phase of the output clock from the divider circuits 70-1 to 70-n with that of a reference clock Cref. The frequency of the reference clock is f₀/2ⁿ. The output voltage of the charge pump 72 is controlled by charging or discharging the electric charge in the internal capacitance of the charge pump 72 based on the comparison result. The lowpass filter 73 integrates the output voltage of the charge pump 72 to remove high frequency components of the output voltage. The voltage controlled oscillator 74 produces an oscillating signal CK having a frequency according to the output voltage of the lowpass filter 73. The frequency of the signal CK is f₀ when the PLL loop is locked.

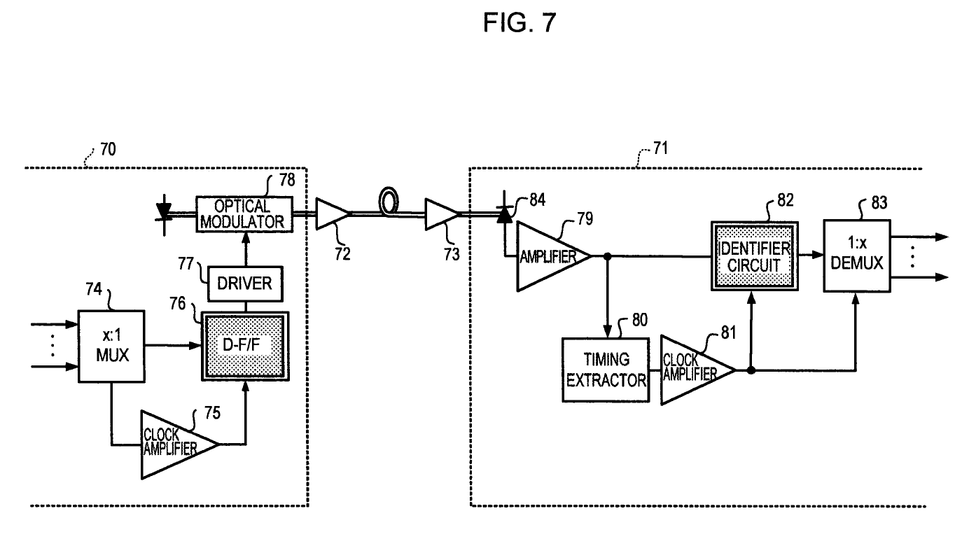

FIG. 7 shows an optical communication system to which a flip-flop circuit according to an embodiment of the present invention is applied. The optical communication system shown in FIG. 7 includes an optical transmitter 70, an optical receiver 71, an optical amplifier 72, and an optical amplifier 73. The optical amplifiers 72 and 73 can be omitted, for example, in a short-range communication system. The optical transmitter 70 includes a multiplexer 74, a clock amplifier 75, a flip-flop circuit, for example D-FF, 76, a driver 77, and an optical modulator 78. The optical receiver 71 includes an amplifier 79, a timing extractor circuit 80, a clock amplifier 81, an identifier circuit 82, a demultiplexer 83, and a photodetector 84. The identifier circuit 82 may also be referred to a “decision circuit”.

In the optical transmitter 70, the multiplexer 74 first multiplexes a plurality of signals. The flip-flop circuit 76 receives the multiplexed signal in synchronization with a clock signal outputted from the clock amplifier 75. The driver 77 drives the optical modulator 78 in accordance with the output from the flip-flop circuit 76, and the optical modulator 78 outputs an optical signal modulated in accordance with the multiplexed signal. In the optical transmitter 70, the flip-flop circuit 76 is a flip-flop circuit, such as either one of the circuits shown in FIG. 2 or 4, that uses the transformation coupling to transmit a clock. Using a flip-flop circuit that uses transformation coupling to transmit a clock allows multiplexed high-frequency data to be acquired in a stable manner.

In the optical receiver 71, the photodetector 84 receives the optical signal and converts it into a current signal. The amplifier 79 amplifies the current signal and converts it into a voltage signal. The timing extractor circuit 80 extracts the clock signal from the voltage signal, and the clock amplifier 81 amplifies the clock signal. The decision circuit 82 identifies the voltage signal outputted from the amplifier 79 as high-level or low-level data in synchronization with the clock output from the clock amplifier 81. The demultiplexer 83 separates the identified data into a plurality of signals. The decision circuit 82 is a flip-flop circuit, for example D-type a flip-flop circuit (D-FF), and receives data in synchronization with the clock signal to determine whether the data is high-level or low-level data. Using the flip-flop circuit shown either in FIG. 2 or in FIG. 4 that uses transformation coupling to transmit a clock allows multiplexed high-frequency data to be received in a stable manner. Further, in the decision circuit 82, an amplifier may be provided in front of the flip-flop circuit.

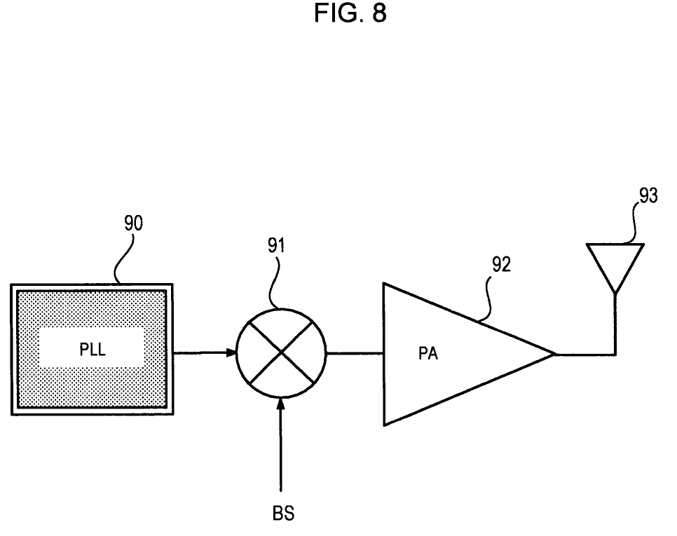

FIG. 8 shows a transmitter that is used in a wireless communication system and to which a flip-flop circuit according to an embodiment of the present invention is applied. The transmitter shown in FIG. 8 includes a PLL circuit 90, a mixer 91, a power amplifier (PA) 92, and an antenna 93.

The mixer 91 multiplies a clock signal produced in the PLL circuit 90 by a baseband signal BS to produce a modulated signal. The power amplifier 92 amplifies the modulated signal produced in the mixer 91 and transmits the amplified signal as a wireless signal from the antenna 93. Using the PLL circuit shown in FIG. 6 described above as the PLL circuit 90 allows a high-speed clock signal at 60 GHz, for example, to be produced in a stable manner even when a low power supply voltage is used.

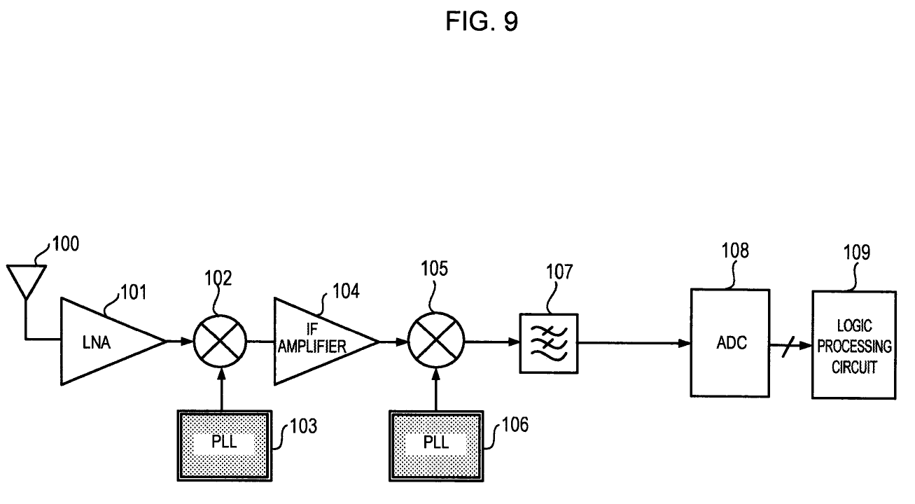

FIG. 9 shows an example of the configuration of a receiver that is used in a wireless communication system and to which a flip-flop circuit according to an embodiment of the present invention is applied. The receiver shown in FIG. 9 includes an antenna 100, a low-noise amplifier (LNA) 101, a mixer 102, a PLL circuit 103, an IF amplifier 104, a mixer 105, a PLL circuit 106, a filter 107, an analog-to-digital converter 108, and a logic processing circuit 109.

The low-noise amplifier (LNA) 101 amplifies a wireless signal received by the antenna 100. The mixer 102 multiplies the received, amplified signal by a signal having a predetermined frequency produced in the PLL circuit 103 to produce an intermediate frequency signal (IF signal) having a lowered frequency. The IF amplifier 104 amplifies the intermediate frequency signal. The mixer 105 multiplies the amplified intermediate frequency signal by a signal having a predetermined frequency produced in the PLL circuit 106 to produce a demodulated signal. The filter 107 extracts the modulated signal, which is then converted into a digital signal in the analog-to-digital converter 108. The logic processing circuit 109 carries out a logical operation according to the thus obtained digital signal.

Using the PLL circuit shown in FIG. 6 for at least either the PLL circuit 103 or the PLL circuit 106 or both allows a high-speed clock signal to be produced in a stable manner even when a low power supply voltage is used.

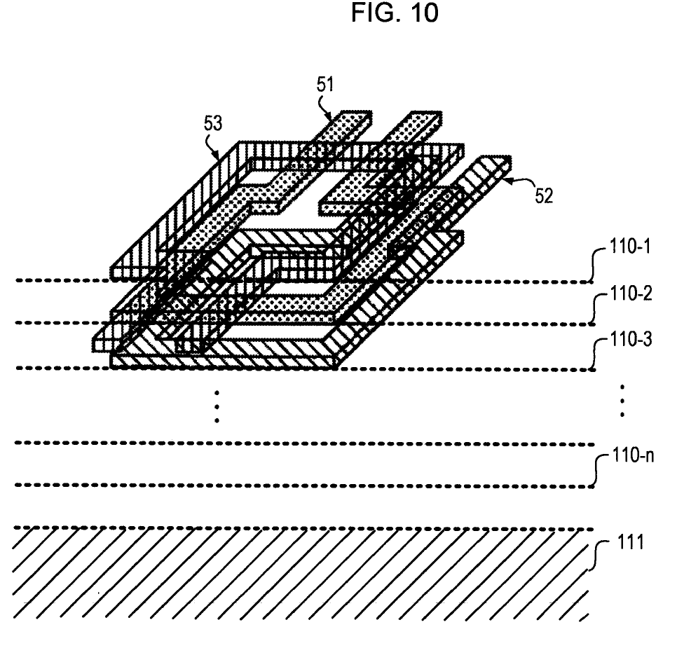

FIG. 10 shows an example of structure of a transformer circuit applicable to an embodiment of the present invention. FIG. 10 shows the structure of the transformer circuit 35 including the first inductor element 51, the second inductor element 52, and the third inductor element 53. Other transformer circuits can also be structured in the same manner.

As shown in FIG. 10, wiring layers 110-1 to 110-n for laying out metal wiring are present over a layer 111. The layer 111 is a layer in which transistors, diodes, resistors, and other components are disposed, and includes a diffusion layer of a substrate and a layer that is immediately over the substrate and in which a polysilicon gate and other structures are disposed. The third inductor element 53 is disposed in the first wiring layer 110-1. The first inductor element 51 is disposed in the second wiring layer 110-2. The second inductor element 52 is disposed in the third wiring layer 110-3.

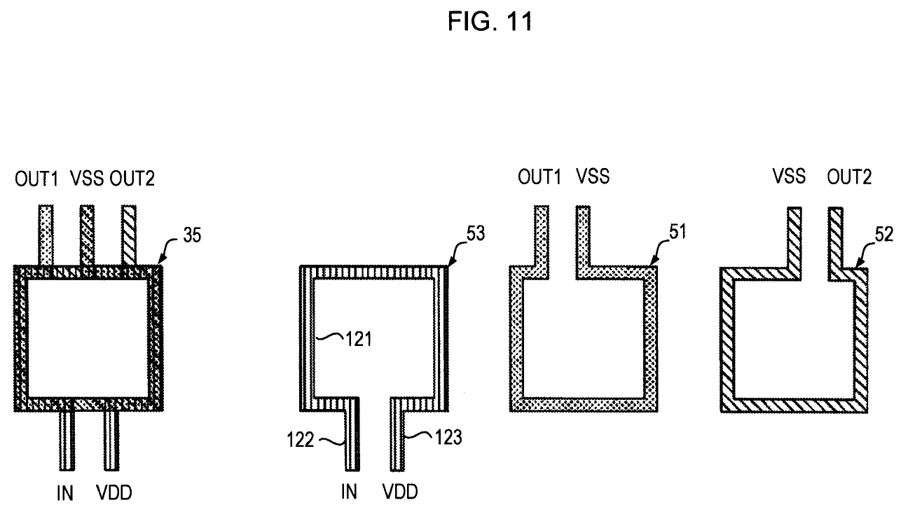

FIG. 11 shows the layout of the inductor elements shown in FIG. 10. As shown in FIG. 11, the third inductor element 53, the first inductor element 51, and the second inductor element 52 each have a coil and terminals. For example, the third inductor element 53 includes a coil 121 shaped into a square with a part of one side open, an input terminal 122 for an input signal IN, and a power supply terminal 123 to which a power supply voltage VDD is applied. The third inductor element 53, the first inductor element 51, and the second inductor element 52 are disposed in the respective wiring layers in such a way that the coils are superimposed. As a result, when viewed from above the wiring layers, the inductor elements are superimposed to form the transformer circuit 35 as shown at the left end of FIG. 11. Reference character VSS denotes a ground voltage. Reference character OUT1 denotes the output signal from the first inductor element 51. Reference character OUT2 denotes the output signal from the second inductor element 52.

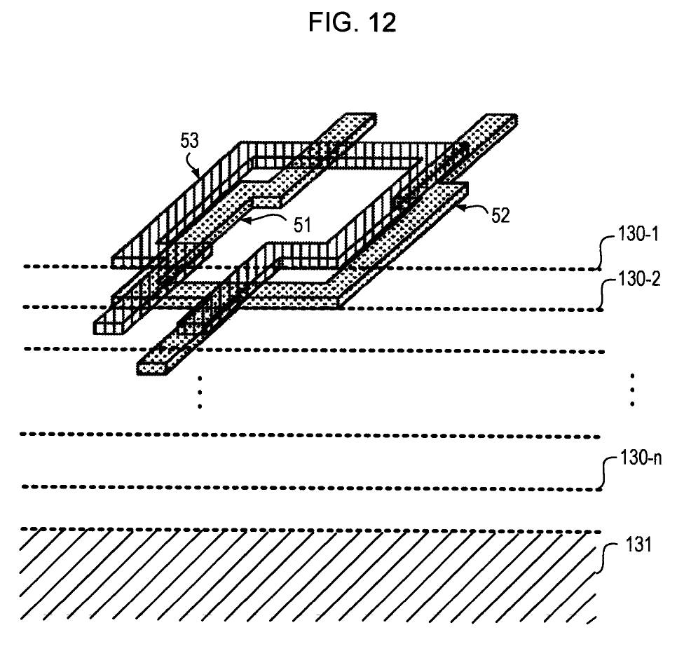

FIG. 12 shows another structure of a transformer circuit applicable to an embodiment of the present invention. FIG. 12 shows the structure of the transformer circuit 35 including the first inductor element 51, the second inductor element 52, and the third inductor element 53. Other transformer circuits can also be structured in the same manner.

As shown in FIG. 12, wiring layers 130-1 to 130-n for laying out metal wiring are present over a layer 131. The layer 131 is a layer in which transistors, diodes, resistors, and other components are disposed, and includes a diffusion layer of a substrate and a layer that is over the substrate and in which a polysilicon gate and other structures are disposed. The third inductor element 53 is disposed in the first wiring layer 130-1. The first inductor element 51 and the second inductor element 52 are disposed in the same second wiring layer 130-2, which is a metal wiring layer.

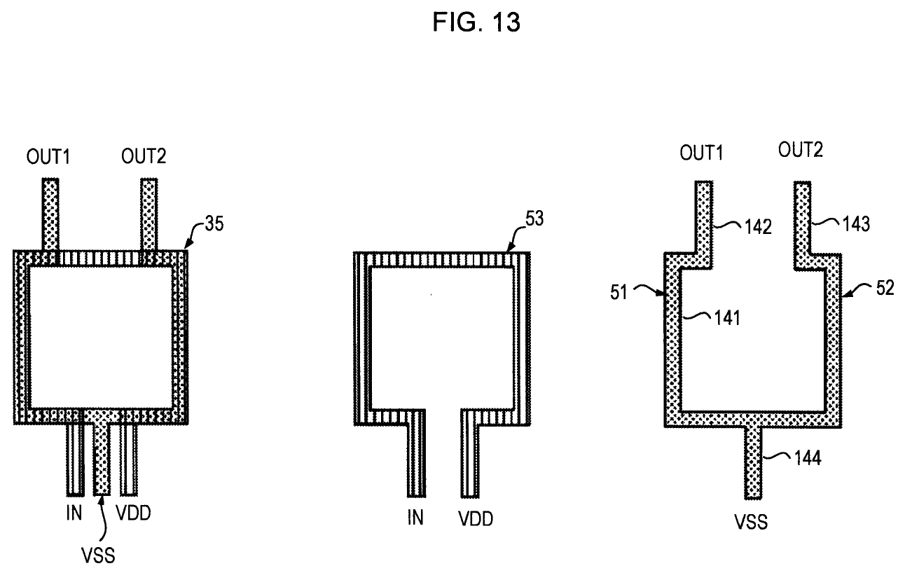

FIG. 13 shows the layout of the inductor elements shown in FIG. 12. The third inductor element 53 shown in FIG. 13 has the same shape as that of the third inductor element 53 shown in FIG. 11. On the other hand, the first inductor element 51 and the second inductor element 52 each include a coil 141 shaped into a square with a part of one side open, an output terminal 142 for an output signal OUT1 of the first inductor element 51, an output terminal 143 for an output signal OUT2 of the second inductor element 52, and a ground terminal 144 to which a ground voltage VSS is applied. The ground terminal 144, the output terminal 142, and the left half of the coil 141 present between the ground terminal 144 and the output terminal 142 serve as the first inductor element 51. The ground terminal 144, the output terminal 143, and the right half of the coil 141 present between the ground terminal 144 and the output terminal 143 serve as the second inductor element 52.

The wiring line of the third inductor element 53 and the wiring lines of the first and second inductor elements 51 and 52 are disposed in the respective wiring layers in such a way that the coils are superimposed. As a result, when viewed from above the wiring layers, the inductor elements are superimposed to form the transformer circuit 35 as shown at the left end of FIG. 13.

What is claimed is:

1. An electric circuit comprising:
a first differential circuit for transmitting input data to a first node;
a second differential circuit for holding data of the first node;
a first clock transmission circuit for flowing a first current in accordance with a clock signal; and
a first transformer circuit for transformer-coupling the first differential circuit with the first clock transmission circuit, and the second differential circuit with the first clock transmission circuit.

2. The electric circuit according to claim 1,
wherein the first transformer circuit includes
a first inductor element coupled to the first differential circuit,
a second inductor element coupled to the second differential circuit, and
a third inductor element coupled to the first clock transmission circuit.

3. The electric circuit according to claim 1,
wherein the first differential circuit transmits the input data to the first node in response to a first voltage level of the clock signal, and
the second differential circuit holds the data of the first node in response to a second voltage level of the clock signal.

4. The electric circuit according to claim 3, further comprising:
a third differential circuit for transmitting the data of the first node to a second node in response to the second voltage level of the clock signal,
a fourth differential circuit for holding the data of the second node in response to the first voltage level of the clock signal,
a second clock transmission circuit for flowing a second current in accordance with the clock signal, and
a second transformer circuit for transformer-coupling the third differential circuit with the second clock transmission circuit and the fourth differential circuit with the second clock transmission circuit.

5. The electric circuit according to claim 4,
wherein the first transformer circuit transformer-couples the third differential circuit with the first clock transmission circuit and the fourth differential amplifier circuit with the first clock transmission circuit.

6. The electric circuit according to claim 5,
wherein the first transformer circuit includes
a first inductor element coupled to the first differential circuit,
a second inductor element coupled to the second differential circuit,
a third inductor element coupled to the third differential circuit,
a fourth inductor element coupled to the fourth differential circuit, and
a fifth inductor element transformer-coupled with the first inductor element, the second inductor element, the third inductor element, and the fourth inductor element, and coupled to the first clock transmission circuit.

7. An electric circuit comprising:
a differential flip-flop circuit for transmitting input data to an output node in response to transition of a clock signal from a first voltage level to a second voltage level, and for holding output node data;
a clock transmission circuit for flowing a current in accordance with the clock signal; and
a transformer circuit for transformer-coupling the flip-flop circuit with the clock transmission circuit.

8. The electric circuit according to claim 7,
wherein the output node of the flip-flop circuit is coupled to an input node of the flip-flop circuit.

9. An electric circuit comprising:
a voltage controlled oscillator;
a divider circuit coupled to the voltage controlled oscillator;
a phase comparator circuit coupled to the divider circuit, and for receiving a reference clock;
a charge pump coupled to the phase comparator circuit; and
a filter coupled to the charge pump and the voltage controlled oscillator,
wherein the divider circuit includes
a differential flip-flop circuit for transmitting input data to an output node in response to transition of a clock signal from a first voltage level to a second voltage level, and for holding the output node data,
a clock transmission circuit for flowing a current in accordance with the clock signal, and
a transformer circuit for transformer-coupling the flip-flop circuit with the clock transmission circuit.

10. The electric circuit according to claim 9,
wherein the output node of the flip-flop circuit is coupled to an input node of the flip-flop circuit.

11. An electric circuit comprising:
a differential flip-flop circuit for transmitting input data to an output node in response to transition of a clock signal from a first voltage level to a second voltage level, and for holding the output node data;
a clock transmission circuit for flowing a current in accordance with the clock signal;
a transformer circuit for transformer-coupling the flip-flop circuit with the clock transmission circuit;
a multiplexer coupled with the flip-flop circuit;
a driver circuit coupled with the flip-flop circuit; and
an optical modulator coupled with the driver circuit.

12. The electric circuit according to claim 11,
wherein the output node of the flip-flop circuit is coupled to an input node of the flip-flop circuit.

13. An electric circuit comprising:
a differential flip-flop circuit for transmitting input data to an output node in response to transition of a clock signal from a first voltage level to a second voltage level, and for holding the output node data;
a clock transmission circuit for flowing a current in accordance with the clock signal;
a transformer circuit for transformer-coupling the flip-flop circuit with the clock transmission circuit;
a photodetector;
an amplifier coupled with the photodetector and the flip-flop circuit; and
a demultiplexer coupled with the flip-flop circuit.

14. The electric circuit according to claim 13,
wherein the output node of the flip-flop circuit is coupled to an input node of the flip-flop circuit.

15. An electric circuit comprising:
a PLL circuit;
a mixer coupled to the PLL circuit and for receiving a baseband signal; and
an amplifier coupled with the mixer,
wherein the PLL circuit includes
a differential flip-flop circuit for transmitting input data to an output node in response to transition of a clock signal from a first voltage level to a second voltage level, and for holding the output node data;
a clock transmission circuit for flowing a current in accordance with the clock signal; and
a transformer circuit for transformer-coupling the flip-flop circuit with the clock transmission circuit.

16. The electric circuit according to claim 15,
wherein the output node of the flip-flop circuit is coupled to an input node of the flip-flop circuit.

17. An electric circuit comprising:
a first amplifier for receiving a signal from an antenna;
a first mixer coupled with the first amplifier;
a second amplifier coupled with the first mixer;
a second mixer coupled with the second amplifier;
an analog-to-digital converter coupled with the second mixer;
a first PLL circuit for supplying a signal having a first frequency to the first mixer; and
a second PLL circuit for supplying a signal having a second frequency to the second mixer,
wherein at least one of the first PLL circuit and the second PLL circuit includes
a differential flip-flop circuit for transmitting input data to an output node in response to transition of a clock signal from a first voltage level to a second voltage level, and for holding the output node data;
a clock transmission circuit for flowing a current in accordance with the clock signal; and
a transformer circuit for transformer-coupling the flip-flop circuit with the clock transmission circuit.

18. The electric circuit according to claim 17,
wherein the output node of the flip-flop circuit is coupled to an input node of the flip-flop circuit.
